(19) United States
(12) Patent Application Publication
(10) Pub. No.: US 2024/0195377 A1
(43) Pub. Date: Jun. 13, 2024

(54) METHOD FOR MAKING A WITH BULK ACOUSTIC WAVE FILTER

(71) Applicant: COMMISSARIAT À L’ENERGIE ATOMIQUE ET AUX ENERGIES ALTERNATIVES, PARIS (FR)

(72) Inventors: Alexandre REINHARDT, GRENOBLE CEDEX 9 (FR); Marie BOUSQUET, GRENOBLE CEDEX 9 (FR)

(21) Appl. No.: 18/538,430

(22) Filed: Dec. 13, 2023

(30) Foreign Application Priority Data
Dec. 13, 2022 (FR) 2213250

(51) Int. Cl. H03H 3/02; H03H 9/17; H03H 9/56

(52) U.S. Cl. CPC H03H 3/02; H03H 9/173; H03H 9/175; H03H 9/176; H03H 9/562; H03H 9/564; H03H 9/568; H03H 2003/021; H03H 2003/025

(57) ABSTRACT

A method for making a bandpass filter including a first and second bulk acoustic wave resonators, the resonant frequency of the second resonator being offset from that of the first resonator by a predetermined offset, the method including providing a piezoelectric on insulator substrate, forming a lower electrode of the first resonator and a lower electrode of the second resonator, assembling by bonding the donor substrate to a receiver substrate, removing the donor substrate with a barrier on the piezoelectric layer, forming an upper electrode of the first resonator and an upper electrode, forming the lower electrodes being preceded by forming a mass overload pattern at the second zone, and/or forming the upper electrodes being preceded by forming a mass overload pattern at the second zone, the total thickness of the mass overload pattern or patterns being chosen to offset the resonant frequency of the second resonator by the offset.

### CROSS-REFERENCE TO RELATED APPLICATIONS

This application claims priority to French Patent Application No. 2213250, filed Dec. 13, 2022, the entire content of which is incorporated herein by reference in its entirety.

### FIELD

The technical field of the invention is that of radiofrequency filters based on bulk acoustic wave resonators.

The present invention relates to a method for manufacturing a radiofrequency filter using several bulk acoustic wave resonators formed on a same substrate of piezoelectric material.

### BACKGROUND

In the field of telecommunications systems, “broadband” radiofrequency filters are required to select the useful radiofrequency signal.

For example, for fifth-generation (or 5G) mobile telephony applications, it is sought to obtain filters with an operating frequency of between 3.3 GHZ and 6 GHz, a relative bandwidth of a few percent, for example 10%, and losses of less than 3 dB in the bandwidth and greater than 45 dB in the rejection bands, that is outside the bandwidth.

For this, solutions based on piezoelectric materials are being developed. Bulk acoustic wave (BAW) filters using several BAW resonators are an example of solutions adapted to mobile telephony standards.

BAW resonators make use of the propagation of acoustic waves in piezoelectric layers. Generally speaking, a BAW resonator comprises a stack of layers formed on a substrate and comprising a lower electrode and an upper electrode framing a portion of a layer formed by a piezoelectric material, referred to as a piezoelectric layer. This stack of layers is also mechanically insulated from the substrate by a stack of layers forming a mechanically insulating device. This device may be an air gap, in which case the BAW resonator is called a FBAR resonator (Film Bulk Acoustic Resonator). Alternatively, the device can be a Bragg mirror structure, in which case the BAW resonator is called a Solidly Mounted Resonator (SMR).

A type of bulk acoustic wave filter with a “ladder” topology is particularly popular, due to its simplicity and adaptability.

With reference to FIG. 1, such a ladder filter 100 comprises a first set J1 of bulk acoustic wave resonators S disposed in series between an inlet 110 and an outlet 120, and a second set J2 comprising a bulk acoustic wave resonator P disposed in parallel and connected to ground.

For the sake of simplicity, the S series bulk acoustic wave resonators are referred to as the S series resonators, and the P parallel bulk acoustic wave resonator is referred to as the P parallel resonator.

The series S resonators all have the same resonant frequency f_{RS}, which corresponds to the desired operating frequency f_{RS} for the filter 100. The S series resonators therefore all have the same anti-resonant frequency f_{AS}.

The resonant frequency f_{RP} of the parallel P resonator, for its part, is offset from the resonant frequency f_{RS} of the series S resonators towards a lower frequency, the offset Δf_{PS} being predetermined so that the antiresonant frequency f_{AP} of the parallel P resonator corresponds to the resonant frequency f_{RS} of the series S resonator. Stated differently, the offset is equal to the result of the difference between the antiresonant frequency f_{AS} and the resonant frequency f_{RS} of the series S resonator.

The electrical response S_{F} of such a filter 100 is given in FIG. 2. The S_{S} response of the series S resonators and the S_{P} response of the parallel P resonator are also displayed. At the resonant frequency f_{RS} of the S series resonators, the electrical signal S_{F} generated by the filter via the S series resonators is maximum. Conversely, at the anti-resonant frequency f_{AS} of the series resonators, the electrical signal S_{F} is redirected to ground or blocked at the input by the series resonators, which have a high impedance, leading to maximum attenuation of the signal S_{F}. Away from these resonance frequencies f_{RS} and anti-resonance frequencies f_{AS}, the filter behaves as a capacitive bridge to attenuate the signal S_{F}.

For such a filter 100 to achieve the broadband specifications previously described, several requirements have to be met.

A first requirement concerns the piezoelectric material. Its electromechanical properties indeed partly determine the performance, in particular the bandwidth and losses of the filter, through a quality factor Q (or figure of merit) and an electromechanical coupling coefficient k² (or kₜ²) characteristic of the filter.

Aluminium nitride AlN and aluminium scandium nitride (Al₁₋ₓScₓN) deposited in thin films, although commonly used in industry, are not suitable piezoelectric materials. The intrinsic electromechanical coupling coefficient of aluminium nitride, at around 7.5%, is indeed too low. As for scandium aluminium nitride, while its intrinsic electromechanical coupling coefficient increases with scandium concentration, its mechanical losses also increase, making it impossible to synthesise filters with satisfactory insertion losses.

It is therefore necessary to replace these materials with ones offering better intrinsic electromechanical performance.

Lithium niobate is one such material.

Document “Large electromechanical coupling factor film bulk acoustic resonator with x-cut LiNbO₃ layer transfer” by Pijolat et al, Applied Physics Letters, 2009, thus showed that a 6.6 μm-thick thin film of lithium niobate formed by layer transfer has an electromechanical coupling factor more than six times that of aluminium nitride (45% versus 7.5% for AlN), making it possible to achieve a bandwidth up to six times wider than the bandwidth of aluminium nitride filters.

Document “High frequency LiNbO₃ bulk Wave resonator” by Gorisse et al, IEEE international Frequency Control Symposium, 2019 based on patent EP2330737B1 describes a way to manufacture a bulk acoustic wave resonator based on such a piezoelectric material. The manufacture method comprises 1) providing a donor substrate comprising a lithium niobate layer having a crystalline orientation along the X-cut plane, 2) implanting ions at a determined depth of the donor substrate to form a brittle plane therein, 3) forming a lower electrode on the lithium niobate layer, 4) transferring the donor substrate to a receiver substrate, leaving the stack comprising the lower electrode and the lithium niobate layer on the receiver substrate, and 5) forming an upper electrode on the piezoelectric layer, at the zone defined by the lower electrode. Such a method beneficially avoids the difficulty of depositing or etching lithium niobate.

Another requirement for obtaining a broadband filter with the aforesaid specifications concerns the ability to offset the resonant frequency of a parallel resonator relative to the resonant frequency of a series resonator with sufficient amplitude and precision.

Several techniques for offsetting frequency of one of the resonators are described. They are all based on the principle of varying the total thickness of the resonator in one of the parallel or series P, S resonators.

All these techniques are mainly described for filters whose piezoelectric material is aluminium nitride. However, lithium niobate has different physical and chemical properties to aluminium nitride. Some of the techniques well known in prior art are therefore not suitable for lithium niobate.

The unsuitable techniques include a first family of techniques consisting of varying the thickness of the layer of piezoelectric material and a second family of techniques consisting of varying the thickness of an electrode by successive steps of depositing and etching a metal layer onto the entire surface of the piezoelectric layer. The first family of techniques uses methods for depositing a piezoelectric layer (to increase thickness) onto the piezoelectric layer that has already been formed, or methods for etching the piezoelectric layer (to reduce thickness). However, lithium niobate is not easy to deposit. In addition, etching it can quickly damage surface of the material (causing roughening or amorphisation thereof), resulting in a loss of its piezoelectric properties. In addition, etching methods are relatively inhomogeneous at the substrate scale, thereby preventing the accuracy and uniformity (that is less than 1% variation at the substrate scale) required to meet tolerances on filter frequency dispersions to be achieved.

The second family of techniques, described for example in U.S. Pat. No. 6,617,249B2, consists precisely in 1) depositing a first metal layer onto the whole of the layer of piezoelectric material, then 2) depositing, onto this first layer and onto a surface corresponding to the parallel P resonator, a layer of metal mass overload for increasing thickness of the upper electrode of the parallel P resonator. The upper electrodes of the S, P series and parallel resonators are then defined by etching together the first metal layer and the mass overload layer.

While depositing and then etching a first electrode layer onto an aluminium nitride piezoelectric layer does not lead to degradation of the aluminium nitride, the same is not true when the piezoelectric layer is made of lithium niobate. Indeed, the chemical compatibility between the electrodes, particularly if they are made of aluminium, and the lithium niobate is different. As a result, depositing the first electrode layer onto the surface of a lithium niobate layer and then removing it by chemical etching leaves visible residues on the surface of the piezoelectric layer. These residues, which are signs of inter-diffusion between the aluminium and the piezoelectric material, induce unwanted roughness and can interfere with the propagation of acoustic waves. Furthermore, inter-diffusion between the aluminium and the piezoelectric material leads to the formation of a mixed oxide, behaving as a dead layer that degrades the piezoelectric properties of the piezoelectric layer.

Techniques adapted to lithium niobate include a third, fourth and fifth family of techniques.

The third family of techniques consists either in thinning one of the electrodes of the S series resonator once it has been formed, or increasing the mass loading of one of the electrodes of the P parallel resonator once it has been formed.

Thinning an electrode consists in partially etching this electrode. However, electrode etching methods do not allow the desired electrode thickness to be achieved with the desired tolerance (less than 1%). In addition, thinning the electrodes leads to an increase in their resistivity, which increases resistive losses in the filter circuit. One alternative, provided in U.S. Pat. No. 6,617,249B2, consists oxidising the electrode on the surface. Here again, the metal oxide is electrically less conductive than the metal of the electrode, which degrades performance of this electrode. The third technique therefore has the disadvantage of degrading filter performance.

The fourth family of techniques consists in varying the thickness of the support layer beneath the parallel P resonator.

Patent U.S. Pat. No. 6,842,089B2 thus describes making a series of masking and etching operations carried out on the substrate before the resonators are manufactured to increase thickness of the support layer under the parallel resonator. The variation in thickness of the support layer, due to its distance from the piezoelectric layer, is significant and has a negative effect on the electromechanical coupling coefficient of the parallel P resonator. One reason for this is that any addition of material under or near the resonator tends to store mechanical energy outside the piezoelectric layer, which is then not converted into electrical energy, as the conversion only takes place in the layer of piezoelectric material. The electromechanical coefficient of the parallel P resonator thus formed is thereby degraded.

Patent U.S. Pat. No. 6,617,249B2 describes modifying a layer thickness closer to the piezoelectric layer. Specifically, this patent describes a solution consisting in depositing a layer, referred to as a mass overload layer, under the lower electrode of a parallel resonator. For this, depositing the mass overload layer is performed on a substrate layer before the step of forming the lower electrode. Although the thickness variation is closer to the piezoelectric layer than the solution previously described, the electromechanical coefficient of the resonator thus formed remains degraded.

The fifth family of techniques consists in depositing a metal mass overload layer onto the upper electrode of the P resonator other than by using deposition/removal of a metal layer over the entire surface of the piezoelectric layer.

Patent U.S. Pat. No. 5,894,647B1 thus describes a first combination of photolithography and etching steps to form the upper electrodes of the S, P series and parallel resonators on top of the layer of piezoelectric material, and then a second combination of photolithography and etching to deposit a mass overload layer only on the upper electrode of the parallel resonator. One drawback is that misalignments between the upper electrode and the mass overload layer can occur, resulting in regions called “overhangs” where the upper electrode is not covered with the mass overload layer, and/or regions where the mass overload layer is in contact with the piezoelectric layer. These regions behave as resonators and introduce parasitic resonances that are detrimental to the filter performance.

To remedy this and define the desired structure for the upper electrode of the parallel P resonator, the same patent describes carrying out a new photolithography and a new deposition of a mass overload layer over a wider zone than the zone defined for the parallel P resonator, and etching the aforementioned regions as well as the edges of the region where the electrode layer and the mass overload layer overlap each other. Etching the mass overload layer is then necessarily a selective etching with respect to the electrode metal, which means that metals with different etching chemistries should be used for the mass overload layer and for the electrodes. The disadvantage is that intermetallic compounds resistant to the etching chemistries can form on the surface of the piezoelectric material. It is thereby necessary to provide an additional mask level to be able to non-selectively etch the edges of the electrodes, which is complex to achieve.

Patent U.S. Pat. No. 6,472,954B1 provides a way of circumventing this problem by describing a step of forming a mass overload layer carried out after forming the resonators (and therefore the upper electrode of the parallel P resonator) and comprising a step of depositing a structured sacrificial layer with a localised loading pattern onto the upper electrode of the parallel P resonator, a step of depositing the mass overload layer onto the structured sacrificial layer, and a step of removing the sacrificial layer and the metal overload layer deposited by lift-off.

Patent U.S. Pat. No. 7,802,349B2 by the same author more specifically describes that the sacrificial layer is a resin mask, and that the removal of this mask is carried out without etching, using so-called “soft” chemistry based on a solution suitable for resins.

By means of the sacrificial layer, the piezoelectric material is protected from inter-diffusion phenomena during the formation of the mass overload layer. However, the removal of this sacrificial layer poses the problem of preserving upper electrodes of the filter resonators. Indeed, removal of the sacrificial layer requires the use of solutions that are generally aggressive towards the metal material used for the electrodes. Cracks and weak points can therefore appear on the electrodes under the combined effect of chemical agents and temperature conditions, which degrades the performance of the resonators and therefore of the filter. Aluminium in particular is very sensitive to these solutions, as is molybdenum, although to a lesser extent. Upper electrodes of parallel resonators can therefore be damaged.

There is therefore a need to improve existing techniques describing the adjustment of the resonant frequency of a parallel P resonator in order to make a broadband filter suitable for mobile telephony applications.

### SUMMARY

An aspect of the invention offers a solution to the problems previously discussed, by providing a method which preserves electrodes of the resonators and can dispense with a succession of steps for depositing and removing a metal layer onto the entire surface of the piezoelectric layer, and which is compatible with the use of a single-crystal piezoelectric material such as lithium niobate.

For this, the method according to an aspect of the invention begins with providing a piezoelectric on insulator substrate and uses an assembly step sandwiched between making the lower part and the upper part of the resonators. In addition, the method enables the lower electrode and/or the upper electrode of the parallel resonator to be thickened prior to forming said electrodes.

An aspect of the invention relates to a method for making a bandpass filter comprising a first bulk acoustic wave resonator and a second bulk acoustic wave resonator, the resonant frequency of the second resonator being offset from the resonant frequency of the first resonator by a predetermined offset, the method comprising the steps of:
providing a piezoelectric on insulator substrate, referred to as the donor substrate, comprising a piezoelectric layer at the top part,
forming a lower electrode of the first resonator on a first predefined zone of the piezoelectric layer, and a lower electrode of the second resonator on a second predefined zone of the piezoelectric layer,
assembling by bonding the donor substrate to a receiver substrate, so that the lower electrodes of the first and second resonators are disposed between the receiver substrate and the donor substrate,
removing, in assembling the receiver substrate and the donor substrate, the donor substrate with a barrier on the piezoelectric layer,
forming, on the piezoelectric layer, an upper electrode of the first resonator at the first zone, and an upper electrode of the second resonator at the second zone,
   forming the lower electrodes being preceded by a step of forming a mass overload pattern at the second zone, referred to as the mass overload pattern of the lower electrode, and/or forming the upper electrodes being preceded by a step of forming a mass overload pattern at the second zone, referred to as a mass overload pattern of the upper electrode, the total thickness of the mass overload pattern(s) being chosen to offset the resonant frequency of the second resonator by the predetermined offset, each mass overload pattern being formed by lift-off of a sacrificial layer formed beforehand on the piezoelectric layer.

Thus, the combination of providing a piezoelectric on insulator substrate, and an assembly step sandwiched between forming the lower part of the resonators (including the lower electrodes) and forming the upper part of the resonators (including the upper electrodes) makes it possible to use single-crystal piezoelectric materials, such as lithium niobate, lithium tantalate, etc., obtained by layer transfer. As these materials have superior intrinsic piezoelectric properties to aluminium nitride, they are compatible with the synthesis of a broadband filter.

This characteristic also has the effect of making both faces (upper and lower) of the piezoelectric layer accessible. This makes it possible to adjust thickness of either electrode of the first resonator or adjust thickness of either electrode of the second resonator. The possibility of varying thickness of the two lower/upper electrodes is particularly beneficial for increasing the filter bandwidth. This characteristic is an improvement on existing techniques.

Furthermore, forming the lower electrodes is preceded by a step of forming a mass overload pattern in the second zone, and/or forming the upper electrodes is preceded by a step of forming a mass overload pattern in the second zone, the mass overload patterns being obtained by depositing a mass overload layer. The total thickness of the mass overload pattern(s) is chosen to offset resonant frequency of the second resonator by the predetermined offset.

As the second zone comprises the zone of the piezoelectric layer corresponding to the second resonator, the electrodes of the second resonator are thickened by a mass overload pattern disposed as follows:
When the lower electrode is thickened, the metal overload pattern is sandwiched between the piezoelectric layer and the lower electrode,
When the upper electrode is thickened, the mass overload pattern is sandwiched between the piezoelectric layer and the upper electrode,
When both electrodes are thickened, a first mass overload pattern is sandwiched between the piezoelectric layer and the lower electrode, and a second mass overload pattern is sandwiched between the piezoelectric layer and the upper electrode.

The benefit of such an arrangement lies in the fact that the variation in thickness is obtained as close as possible to the piezoelectric layer, which makes it possible to preserve the electromechanical coupling coefficient of the second resonator as well as possible, and therefore to improve performance of the filter. It should be noted that this characteristic is different from prior art, which describes a mass overload layer disposed on the upper electrode or under the lower electrode, therefore further away from the piezoelectric layer.

Finally, as the mass overload patterns are formed prior to forming the electrodes, forming the patterns cannot damage metal of the electrodes. The resonator electrodes are therefore preserved.

For these reasons at least, the method according to an embodiment of the invention makes it possible to improve existing techniques describing adjustment of the resonant frequency of a resonator, while being compatible with the use of a single-crystal piezoelectric material. The method according to an embodiment of the invention is thus suitable for making a broadband filter to the specifications required, for example, for mobile telephony.

Beneficially, forming each mass overload pattern by lift-off of a sacrificial layer formed beforehand on the piezoelectric layer comprises the following sub-steps of:
depositing a sacrificial layer onto the entire surface of the piezoelectric layer,
defining an aperture through the sacrificial layer at the second zone, the aperture opening onto the piezoelectric layer at said second zone,
depositing a mass overload layer so as to cover the piezoelectric layer only at the aperture and to cover the sacrificial layer outside the aperture,
removing the stack formed by the sacrificial layer and the mass overload layer by lift-off removal of the sacrificial layer, said removing leaving the mass overload layer on the piezoelectric layer only at the second zone to form the mass overload pattern.

Thus, the mass overload pattern or patterns are formed without the need for an etching operation likely to give rise to inter-diffusion phenomena that could damage the piezoelectric layer. The sacrificial layer therefore makes it possible to protect (preserve) the piezoelectric layer of the resonators, and thus preserve its intrinsic piezoelectric properties.

Beneficially, the mass overload pattern of the lower electrode is formed by a material identical to the mass overload pattern of the upper electrode and has a thickness identical to said mass overload pattern of the upper electrode.

Thus, two mass overload layers are disposed symmetrically between the piezoelectric layer and the lower electrode of the second resonator, and the piezoelectric layer and the upper electrode of the second resonator, respectively. Stated differently, the second resonator has a symmetrical structure with respect to a central plane of the piezoelectric layer.

This characteristic is beneficial for achieving a wide bandwidth without increasing losses in this bandwidth. Indeed, to achieve certain wide bandwidths, the amount of mass is such that it requires a mass overload layer that is relatively thick compared to the other layers. This would degrade symmetry of the second resonator, resulting in a reduction in the electromechanical coupling coefficient and also in the excitation of asymmetric vibration modes, one limiting possibility of achieving a wide bandwidth, the other limiting rejection at the excitation frequency of the antisymmetric vibration modes. By distributing this amount of mass symmetrically between the two mass overload layers of the lower and upper electrodes, these phenomena of parasitic resonance and degradation of the electromechanical coupling coefficient are avoided.

Beneficially, the mass overload pattern of the lower electrode is formed by a material identical to the material of the lower electrodes, and the mass overload pattern of the upper electrode is formed by a material identical to the material of the upper electrodes, and the second zone is laterally wider than the second resonator.

Thus, the second resonator can be laterally redefined at the end of making the filter to eliminate potential parasitic resonance phenomena at its edges. Since a same material is used for the mass overload layer and the electrode associated therewith, redefining the second resonator can be performed by removing the stack formed by the mass overload layer and the electrode located around the zone defined for the second resonator in a single step. This removal is simple to carry out because it does not give rise to intermetallic compounds that complicate etching.

Beneficially, the method can comprise forming a mechanical insulation structure under the first resonator and a mechanical insulation structure under the second resonator.

The mechanical insulation structures insulate the resonators from the receiver substrate and enable them to operate.

According to a first alternative embodiment, the method comprises a step of forming a Bragg structure on the lower electrode of the first resonator and a Bragg structure on the lower electrode of the second resonator, said step of forming the Bragg structures being carried out between forming the lower electrodes and the assembly step.

The Bragg structures are mechanical insulation structures for insulating the resonators from the receiver substrate.

According to a second alternative embodiment, the method comprises steps for forming an air cavity of the first resonator and an air cavity of the second resonator, said steps being as follows:
between forming the lower electrodes and the assembly step, forming a box on and around the lower electrode of the first resonator, and a box on and around the lower electrode of the second resonator, the boxes comprising a sacrificial layer,
after the assembly step and prior to forming the upper electrodes, forming through the piezoelectric layer an aperture to reach the box located on and around the lower electrode of the first resonator, and an aperture to reach the box located on and around the lower electrode of the second resonator,
after the step of forming the upper electrodes, removing the sacrificial layer through the apertures to release the boxes and fill them with air.

The air cavities enable the resonators to be insulated from the receiver substrate.

Beneficially, the method comprises, after the step of forming the upper electrodes, an additional step of depositing onto the upper face of the band-pass filter, and only onto the upper electrodes, a metal layer referred to as an over-metallisation layer.

The purpose of this over-metallisation layer is to consolidate electrodes electrically, the metal layer limiting resistive losses of the upper electrodes.

In addition to the characteristics just discussed in the preceding paragraphs, the method according to an aspect of the invention may have one or more additional characteristics from among the following, considered individually or according to any technically possible combinations:
The piezoelectric layer is formed by a single-crystal piezoelectric material.
The single crystal piezoelectric material is chosen from one of the following materials: lithium niobate, lithium tantalate, potassium niobate, single crystal scandium aluminium nitride.
The lower and upper electrodes are formed by one of the following materials: aluminium, molybdenum, tungsten, ruthenium or iridium.

The invention and its different applications will be better understood upon reading the following description and upon examining the accompanying figures.

### BRIEF DESCRIPTION OF THE FIGURES

The figures are set forth by way of indicating and in no way limiting purposes of the invention.

FIG. 1 schematically represents the structure of a low-pass filter of prior art, said filter using two bulk acoustic wave resonators disposed in series, and one bulk acoustic wave resonator disposed in parallel,

FIG. 2 represents the electrical response as a function of frequency of the filter of FIG. 1, as well as the individual electrical responses of the series and parallel resonators of FIG. 1,

FIGS. 3A to 31 schematically represent steps of a method according to a first embodiment of the invention,

FIGS. 4A to 4D schematically represent sub-steps of the second step of the method of FIG. 3B,

FIGS. 5A to 51 schematically represent steps of a method according to a second embodiment of the invention,

FIGS. 6A to 6J schematically represent steps of a method according to a third embodiment of the invention.

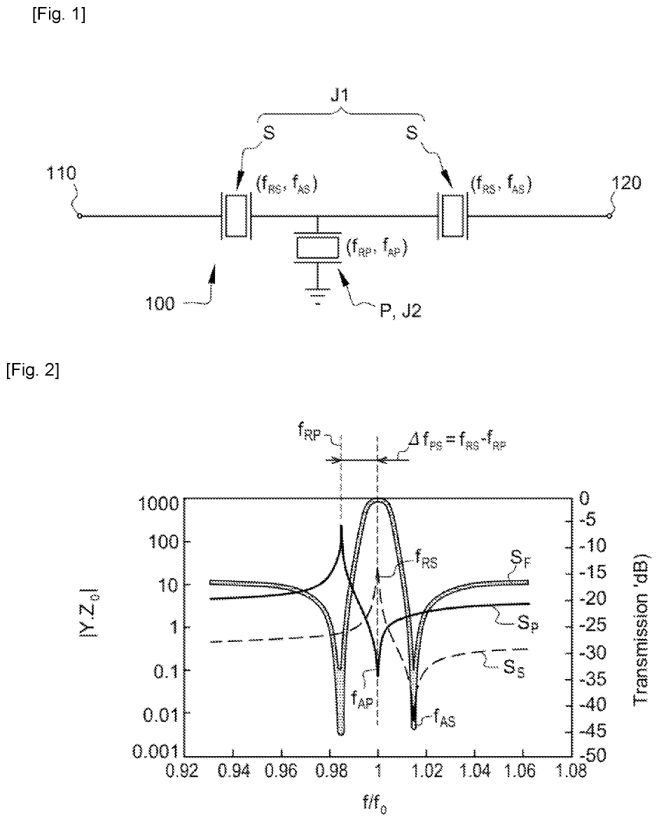

### DETAILED DESCRIPTION

It should be remembered beforehand that, in general and as is well known to those skilled in the art, a bandpass filter is made from at least two electrically coupled bulk acoustic wave resonators arranged in a so-called ladder structure. These two resonators have an offset in their resonant frequencies which is achieved by dimensioning a mass overload layer formed at the lower electrode or the upper electrode of one of the resonators.

The total thickness of the mass overload layer determines frequency offset between the resonant frequencies of the two resonators. Thickness control (tolerance) determines accuracy of this offset.

If broadband performance is required for the filter, it is necessary to form a mass overload layer thickness in the order of 100 nm to 150 nm with a tolerance of less than 2 nm, without damaging either the piezoelectric layer or the electrodes. By “broadband performance”, it is meant an operating frequency of between 3.3 GHZ and 6 GHZ, a bandwidth of between 330 MHz and 600 MHZ, losses of less than 3 dB in the bandwidth and greater than 45 dB in the rejection bands.

In the remainder of the description, the resonator of the filter not receiving a mass overload layer will be arbitrarily referred to as the “first resonator”, and the resonator of the filter receiving the mass overload layer will be arbitrarily referred to as the “second resonator”. With reference to the “Background to the invention” part, the first resonator is assimilated to the S series resonator, and the second resonator to the P parallel resonator. Furthermore, the first and second resonators are FBAR type or SMR type bulk acoustic wave resonators.

The method according to an embodiment of the invention is especially remarkable in that the second resonator can receive a mass overload layer at either, or both, of its electrodes.

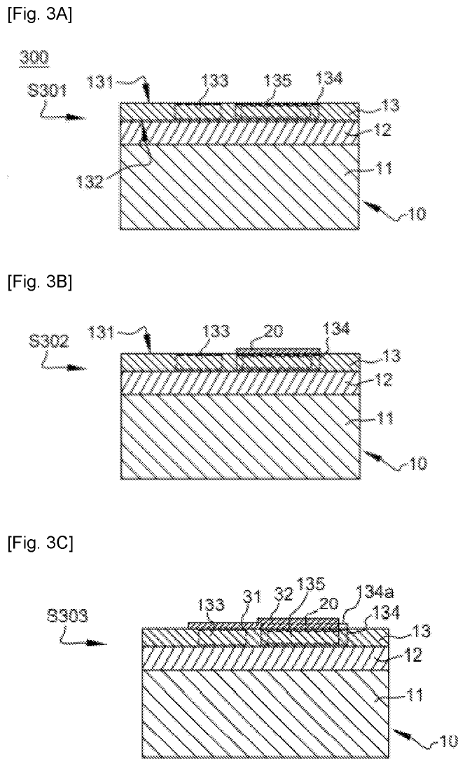

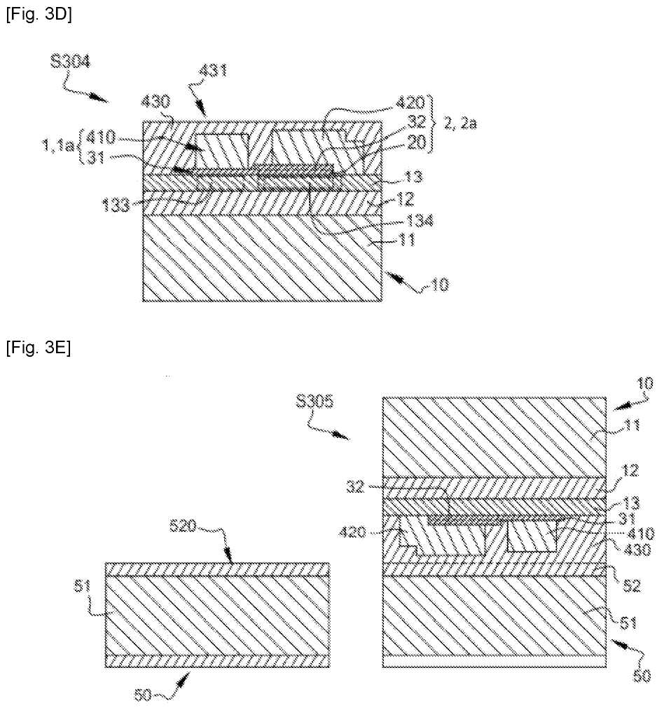

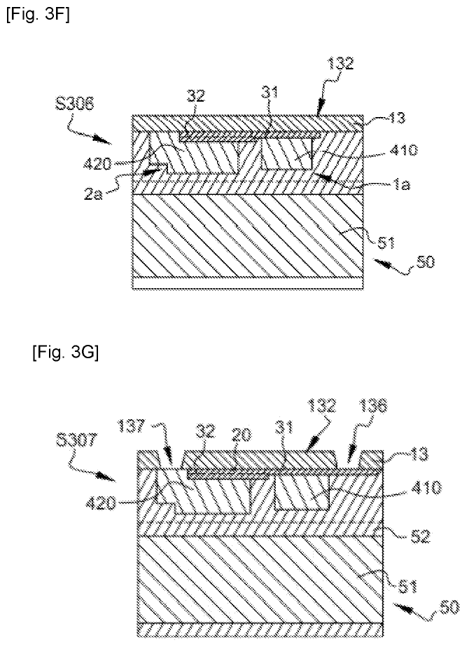

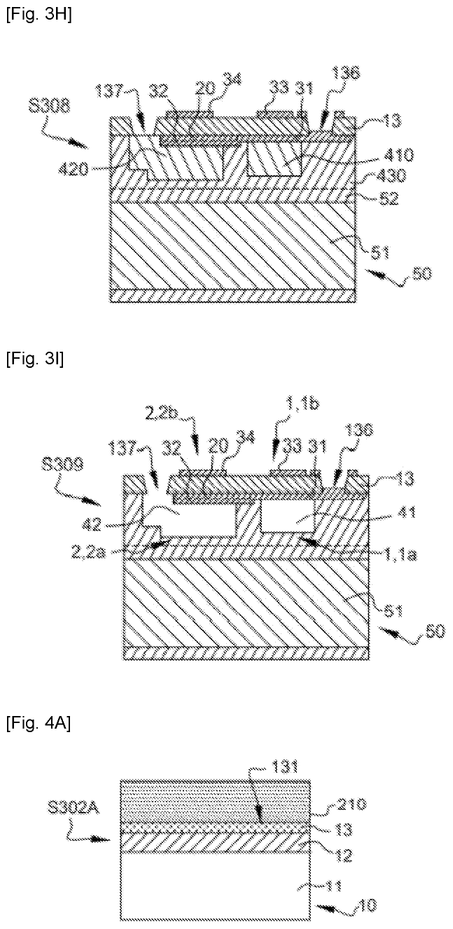

FIGS. 3A to 31 schematically represent steps of a method 300 according to a first embodiment of the invention.

According to this first embodiment and with reference, for example, to FIG. 3I, the first and second resonators 1, 2 are of the FBAR type, and the second resonator 2 receives a mass overload layer 20 at its lower electrode 32.

The first step S301 illustrated in FIG. 3A consists in providing a donor substrate 10 comprising on its upper part a layer 13 of piezoelectric material, referred to as the piezoelectric layer 13. The piezoelectric layer 13 has a first face 131 and a second face 132 (also called the upper face 132) and comprises a first zone 133 in which the first resonator 1 will be defined and a second zone 134 in which the second resonator 2 will be defined.

The second zone 134 may comprise a zone 135, referred to as the active zone 135, which predefines the second resonator more precisely. The second zone 134 is laterally wider than the active zone 135.

It should be noted that zones 133, 134 and 135 do not presume exact dimensions of the resonators 1, 2.

In an embodiment, the donor substrate 10 is a piezoelectric on insulator (POI) substrate. The POI substrate 10 comprises a first substrate layer 11, for example of silicon, a dielectric layer 12, for example of silicon oxide, and the piezoelectric layer 13.

The piezoelectric layer 13 is beneficially formed by a single crystal piezoelectric material. The piezoelectric layer 13 is thereby formed by a known layer transfer technique onto the POI substrate 10.

The piezoelectric layer 13 is, for example, a lithium niobate layer with a Y+36° crystalline cross-section and a thickness of 500 nm. Thus, the piezoelectric layer 13 is able to promote propagation of longitudinal waves with a high propagation speed (7316 m/s) allowing synthesis of a filter operating at frequencies above 4 GHz. It will be appreciated that other crystalline orientations may be suitable, for example Z, or X, or Y+163° crystalline cross-sections. The thickness of the piezoelectric layer 13 is thereby adapted according to the chosen crystalline orientation and the desired filter performance.

Other single-crystal piezoelectric materials may be chosen, such as lithium tantalate LiTaO₃, potassium niobate KNbO₃, and single-crystal scandium Al₁₋ₓScₓN.

The second step S302, illustrated in FIG. 3B, follows the first step S301. It consists in forming a mass overload pattern 20 on the first face 131 of the piezoelectric layer 13, at the second zone 134.

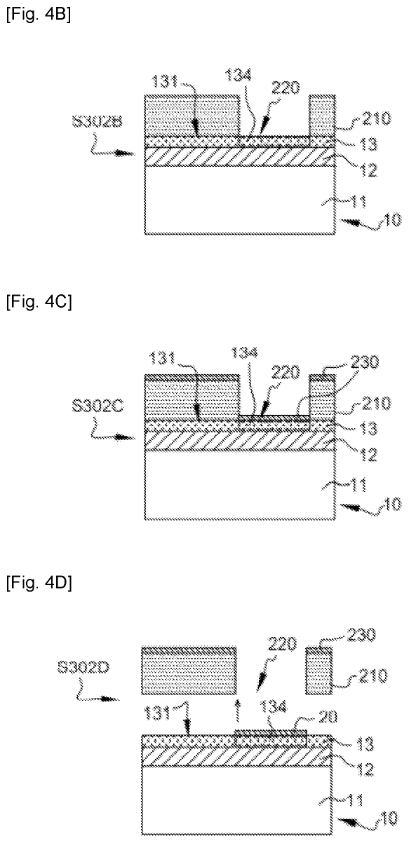

Forming the mass overload pattern 20 comprises the sub-steps S302A, S302B, S302C and S302D illustrated in FIG. 4A, FIG. 4B, FIG. 4C and FIG. 4D respectively.

The first sub-step S302A consists in depositing onto the first face 131 of the piezoelectric layer 13 a sacrificial layer 210 so as to cover the entire surface of the piezoelectric layer 13. The sacrificial layer 210 is in an embodiment a photosensitive resin.

The second sub-step S302B consists in defining a loading pattern 220 through the sacrificial layer 210 deposited and at the second zone 134. The loading pattern 220 is an aperture formed in the sacrificial layer 210 over its entire thickness. It is defined, for example, by exposure and chemical development of the sacrificial layer 210.

At the end of this sub-step S302B, the sacrificial layer 210 covers the first face 131 with the exception of the second zone 134 which is located at the loading pattern 220.

The third sub-step S302C consists in depositing a mass overload layer 230 onto the entire surface of the sacrificial layer 210 structured with the loading pattern.

The mass overload layer 230 is formed by a metal material, for example aluminium.

The metal material chosen for the mass overload layer 230 is beneficially identical to the material chosen to form the lower electrode 32.

The thickness of the mass overload layer is, for example, 150 nm.

At the end of this sub-step S302C, the mass overload layer has reached the first face 131 of the piezoelectric layer 13 only at the loading pattern 220, and has covered the surface of the sacrificial layer 210 where the loading pattern is not present.

The fourth sub-step S302D consists in removing the stack formed by the sacrificial layer 210 and the mass overload layer 230 using a so-called lift-off technique. More specifically, the sacrificial layer 210 is removed by dissolving it in a solvent (for example a solvent suitable for the resin chosen for the sacrificial layer 210). As it is removed, the sacrificial layer 210 lifts off the mass overload layer covering it.

At the end of sub-step S302D, the mass overload layer 230 remains only at the second zone 134, where it was in direct contact with the first face 131 of the piezoelectric layer 13, and forms the mass overload pattern 20 therein.

Thus performed, the step S302 of forming the mass overload pattern 20 preserves the surface of the piezoelectric layer 13. Indeed, this step S302 does not require any (chemical or physical) etching step of a metal layer on the first face 131 of the piezoelectric layer 13. The absence of etching makes it possible to avoid damage such as cracks or roughness on this piezoelectric layer 13, particularly if it is formed by lithium niobate.

It should moreover be noted that the methods in the state of the art generally do not use this step S302 because the aluminium nitride, which is the most commonly used piezoelectric material, is damaged by the solvent used to dissolve the sacrificial layer 210. This is not the case with the chosen piezoelectric materials, which remain crack-free and smooth after the solvent has been applied.

The second step S302 is followed by a third step S303, illustrated in FIG. 3C, consisting in forming the lower electrode 31 of the first resonator 1 and the lower electrode 32 of the second resonator 2.

For this, step S302 comprises depositing a layer of a metal material, the latter being selected from (but not limited to) the following: aluminium, molybdenum, tungsten, ruthenium, iridium.

For example, the metal material (and therefore the lower electrodes 31, 32) is aluminium.

The thickness of the layer of metal material (and therefore of the lower electrodes 31, 32) is, for example, 100 nm.

Depositing the metal layer is followed by a photolithography operation—comprising spreading a resin, exposing it and then developing patterns, a wet etching operation in a solution adapted to the metal layer, and a resin removal operation, all to define the shape of the lower electrodes 31, 32 of the first and second resonators 1, 2. The lower electrode 31 of the first resonator 1 can be connected to the lower electrode 32 of the second resonator 2 as is illustrated in FIG. 3C, or it can be separated from this lower electrode 32 of the second resonator 2.

It should be noted that the etching operation is carried out outside the first zone 133 defined for the first resonator 1 and outside the active zone 135 predefined for the second resonator 2.

When the second zone 134 is larger than the active zone 135, the etching operation to define the lower electrodes 31, 32 is also carried out at the mass overload pattern 20, in the zone 134a of the second zone 134 adjacent to the active zone 135.

When the mass overload layer 230 is formed by a material identical to the lower electrodes 31, 32 (as illustrated in FIG. 3C), this etching operation is carried out in a single step. This simplifies the method because it is not necessary to provide different etching chemistries. Moreover, it avoids the risk of forming intermetallic compounds on the piezoelectric layer in proximity to the second resonator 2.

At the end of this step S303, the lower electrodes 31, 32 of the first and second resonators 1, 2 are therefore well defined and the piezoelectric layer 13 is preserved from intermetallic contaminants in the first zone 133 and the active zone 135.

Step S303 is followed by step S304, illustrated in FIG. 3D, for beginning forming a cavity-type mechanical insulation structure 41 (see FIG. 3I) in the first zone 133, and a cavity-type mechanical insulation structure 42 in the second zone 134.

For this, step S304 consists in forming a box 410, referred to as a release box, on and around the lower electrode 31 of the first resonator 1, and another release box 420 on and around the lower electrode 32 of the second resonator 2.

For this, depositing a sacrificial layer, for example 300 nm thick is performed. The sacrificial layer is in an embodiment formed by amorphous silicon. Photolithography, dry etching and resin removal are then carried out successively to define the shape of the release boxes 410, 420.

Step S304 ends with depositing a dielectric layer 430, for example of silicon oxide, for example using a plasma enhanced chemical vapour deposition (PECVD) technique, followed by chemical mechanical polishing of the upper surface 431 of the dielectric layer formed.

At the end of this step S304, the first part 1a of the first resonator 1 and the second part 2a of the second resonator 2 are formed on the first face 131 of the piezoelectric layer 13. The donor substrate 10 further has a planar and smooth free surface 431, corresponding to the upper surface 431 of the dielectric layer formed.

Step S305, which follows step S304, is illustrated in FIG. 3E. Its purpose is to assemble by bonding the donor substrate 10 obtained at the end of step S304 to a receiver substrate 50, with the lower electrodes 31, 32 (and the release boxes 410, 420) disposed between the receiver substrate 50 and the donor substrate 10.

The receiver substrate 50 is a silicon support substrate 51 having high resistivity (at least 3 kΩ·cm, for example more than 10 kΩ·cm) covered with a dielectric layer 52, for example of silicon oxide, smoothed by chemical mechanical polishing.

The assembly step S305 first consists in turning over the donor substrate obtained at the end of step S304 to transfer the planarised free face 431 of the device formed by the donor substrate 10 (see FIG. 3D) to the upper face 520 of the receiver substrate 50.

Direct bonding is then achieved by a heat treatment (or annealing) referred to as bond consolidation.

The next step is step S306 illustrated in FIG. 3F. This step S306 consists in removing the silicon substrate layer 11 and the dielectric layer 12 from the donor substrate 10 on the assembly formed in step S305. For this, mechanical lapping and then chemical etching in a solution comprising tetramethylammonium hydroxide (TMAH) are performed on the silicon substrate layer 11, and chemical etching based on a solution comprising hydrofluoric acid (HF) is performed on the dielectric layer 12.

At the end of step S306, the receiver substrate 50 comprises the first part 1a of the first resonator 1, as well as the first part 2a of the second resonator 2 and has a free face corresponding to the second face 132 of the piezoelectric layer 13 at the top thereof.

With reference to FIG. 3G, step S307 consists in forming apertures 136, 137 through the piezoelectric layer 13 from the second face 132. One of the apertures 136 reaches the lower electrodes 31, 32, and the other aperture 137 reaches the release box 420. Another aperture (not represented in FIG. 3G) reaches the release box 410.

For this, photolithography, followed by ion beam etching (IBE) of the piezoelectric layer and then resin removal are conducted.

Step S308, which follows step S307, is illustrated in FIG. 3H. It consists in forming the upper electrode 33 of the first resonator 1 and the upper electrode 34 of the second resonator 2.

Similarly to step S303 of forming the lower electrodes 31, 32, step S308 comprises depositing a layer of a metal material, the latter being chosen from (but not limited to) the following: aluminium, molybdenum, tungsten, ruthenium, iridium.

The thickness of the layer of metal material (and therefore of the upper electrodes 33, 34) is, for example, 100 nm.

The upper electrodes 33, 34 are beneficially formed by the same metal material as the lower electrodes 31, 32, for example aluminium.

Depositing the metal layer is followed by a photolithography operation comprising depositing a resin, a wet etching operation in a solution adapted to the metal layer, and a resin removal operation to define shape of the upper electrodes 33, 34 of the first and second resonators 1, 2. With reference to FIG. 3H, the upper electrode 33 of the first resonator 1 is separated from the upper electrode 34 of the second resonator 2.

The next step S309, illustrated in FIG. 3I, consists in releasing the release boxes 410, 420 by dissolving the amorphous silicon sacrificial layer with XeF₂ gas.

Thus, the release boxes fill with air and form the air cavities 41, 42 of the first and second resonators 1, 2.

At the end of step S309, the first part 1a, 1b of the first resonator 1 and the second part 2a, 2b of the second resonator 2 are made, and the bandpass filter is made.

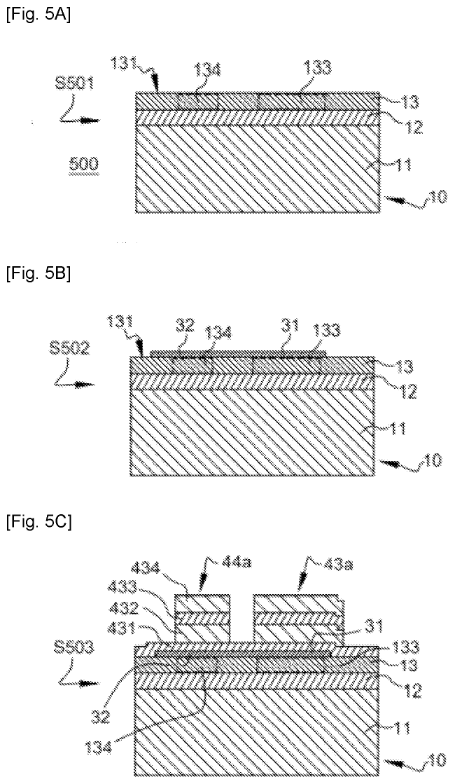

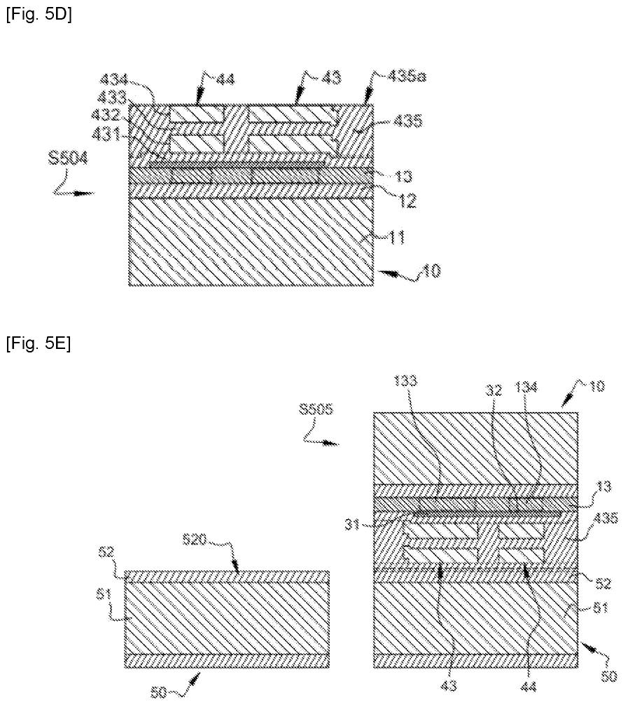

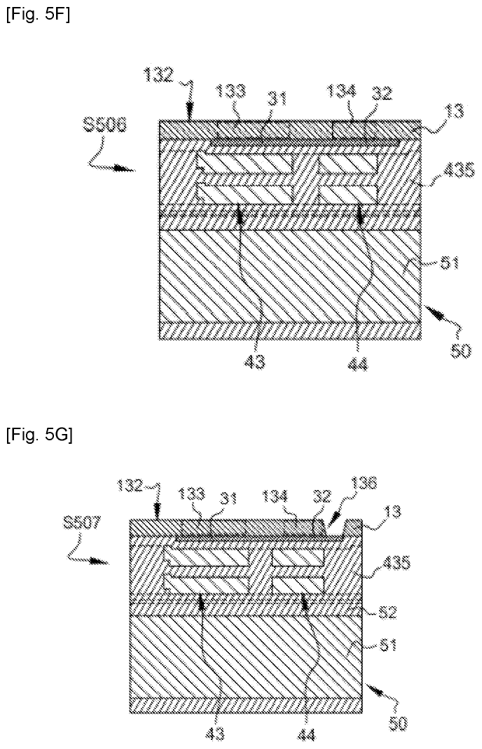

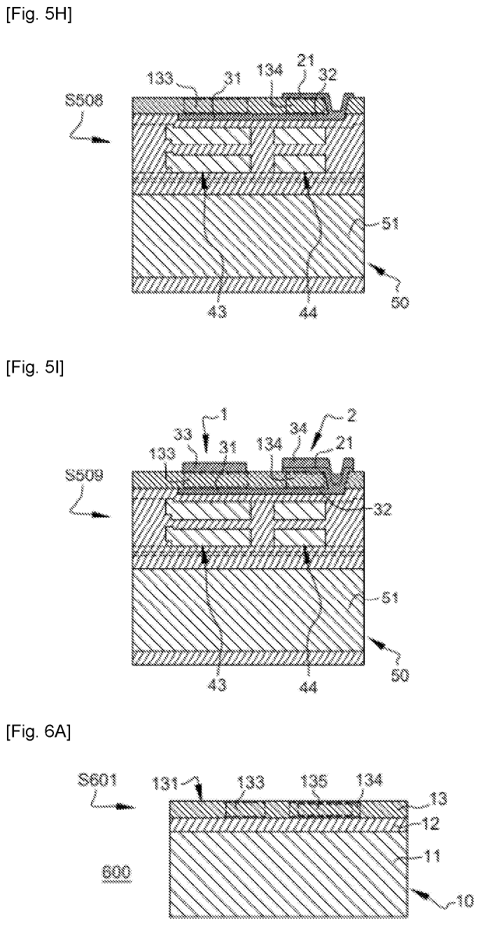

FIGS. 5A to 51 schematically represent the steps of a method 500 according to a second embodiment of the invention.

According to this second embodiment and with reference, for example, to FIG. 5I, the first and second resonators 1, 2 are of the SMR type, and the second resonator 2 receives a mass overload layer 21 at its upper electrode 34.

The method 500 comprises the steps S501, S502, S503, S504, S505, S506, S507, S508 and S509 represented in FIG. 5A, FIG. 5B, FIG. 5C, FIG. 5D, FIG. 5E, FIG. 5F, FIG. 5G, FIG. 5H and FIG. 5I respectively.

Steps S501, S502, S505, S506 and S509 are respectively analogous to steps S301, S303, S305, S306 and S308 of the method 300 according to the first embodiment.

Step S507, illustrated in FIG. 5G, differs from step S307 (see FIG. 3G) only in that there are only apertures 136 reaching the lower electrodes 31, 32 and intended to serve as an electrical via through the piezoelectric layer 13.

The second embodiment (method 500) is distinguished from the first embodiment (method 300) in two ways.

Firstly, step S301 of forming a mass overload pattern 20 on the first face 131 of the piezoelectric layer 13 is not carried out but is replaced with step S508 of forming a mass overload pattern 21 on the second face 132 (see FIG. 5F) of the piezoelectric layer 13, at the second zone 134.

This step S508 is illustrated in FIG. 5H. It is carried out as an extension of the step S507 of forming an aperture 136 through the piezoelectric layer 13, and before the step S509 of forming the upper electrodes 33, 34 of the resonators 1, 2.

The mass overload pattern 21 can cover the aperture 136, which has been formed in the previous step S507 and is to connect the lower electrode 32 of the second resonator 2. Thus, the mass overload pattern 21 acts as a conductive via at the same time as thickening the upper electrode 34.

Step S508 follows the same sub-steps S302A to S302D previously described and represented in FIGS. 4A, 4B, 4C and 4D. Thus, forming the mass overload pattern 21 is performed without damaging the second face 132 of the piezoelectric layer 13.

Secondly, steps S304, S307 and S309 for forming the air cavities 41, 42 (these enabling FBAR-type resonators 1, 2 to be formed) are replaced with steps S503 and S504. These are designed to form Bragg structures 43, 43 (see FIG. 5D) for forming SMR-type resonators 1, 2 (see FIG. 5I).

Step S503, illustrated in FIG. 5C, is to begin formation of Bragg structures 43, 43.

Specifically, step S503 consists in forming a stack of layers 43a on the lower electrode 31 of the first resonator 1 and a stack of layers 44a on the lower electrode 32 of the second resonator 2.

For this, step S503 comprises the following successive sub-steps of:
Depositing a first layer 431 of silicon oxide onto the entire surface of the piezoelectric layer 13, the first layer 431 covering the lower electrodes 31, 32 of the first and second resonators 1, 2.
Depositing a second layer 432 of tungsten onto the first layer 431. A tie layer of titanium, titanium oxide, titanium nitride or any other material known in the state of the art may be deposited beforehand.
Defining the second layer 432 to begin forming the stack 43a in the first zone 133 and the second stack 44a at the second zone 134. For this, a combination of photolithography and dry etching, for example by RIE (Reactive Ion Etching) is performed.
Depositing a third layer 433 of silicon oxide onto the second layer 432.
Depositing a fourth layer 434 of tungsten onto the third layer 433. As previously, a tie layer of titanium, titanium oxide, titanium nitride or any other material known in the art may be deposited beforehand.
Defining the fourth layer 434 to continue the first stack 43a and the second stack 44a by a combination of photolithography and dry etching.
Removing the resin used for photolithography.

The first, second, third and fourth layers 431, 432, 433 and 434 form the Bragg mirrors of the Bragg structures 43, 44.

Alternatively, it is possible to form the Bragg structures 43 and 44 by only conducting a single step of simultaneous etching of the metal layers 432 and 434 and the intermediate dielectric layer 433. For this, the following succession of sub-steps is used:
Depositing a first layer 431 of silicon oxide onto the entire surface of the piezoelectric layer 13, the first layer 431 covering the lower electrodes 31, 32 of the first and second resonators 1, 2.
Depositing a second layer 432 of tungsten onto the first layer 431. A tie layer of titanium, titanium oxide, titanium nitride or any other material known in the art may be deposited beforehand.
Depositing a third layer 433 of silicon oxide onto the second layer 432.
Depositing a fourth layer 434 of tungsten onto the third layer 433. As previously, a tie layer of titanium, titanium oxide, titanium nitride or any other material known in the art may be deposited beforehand.
Defining the Bragg mirrors by photolithography and ion beam etching of the fourth, third and second layers 434, 433 and 432 to continue the first stack 43a and the second stack 44a.
Removing the resin used for photolithography.

Step S504, illustrated in FIG. 5D, consists in depositing a thick layer 435, of 2.5 μm for example by PECVD, of silicon oxide onto the donor substrate 10.

The silicon oxide layer 435 completely covers the stacks 43a, 44a formed in step S503 and has an upper surface 435a.

A back mask may be used in this step S504. It comprises a combination of photolithography and partial etching of the silicon oxide layer 435 and resin removal to level the upper surface 435a between the top of the Bragg mirrors and surrounding zones.

This surface is then planarised by polishing with a barrier on the fourth layer 434.

Thus, the method 500 according to this second embodiment relates to making a bandpass filter using SMR-type resonators, and comprises, prior to forming the upper electrodes 33, 34, forming a mass overload pattern 21 sandwiched between the piezoelectric layer 13 and the upper electrode 34 of the second SMR resonator. The benefit of doing this over placing the mass overload layer between the piezoelectric layer 13 and the lower electrode 31 is to simplify the polishing sub-step of step 504, since the absence of the mass overload layer below the lower electrode ensures that the upper surfaces of structures 43 and 44 are located at the same height.

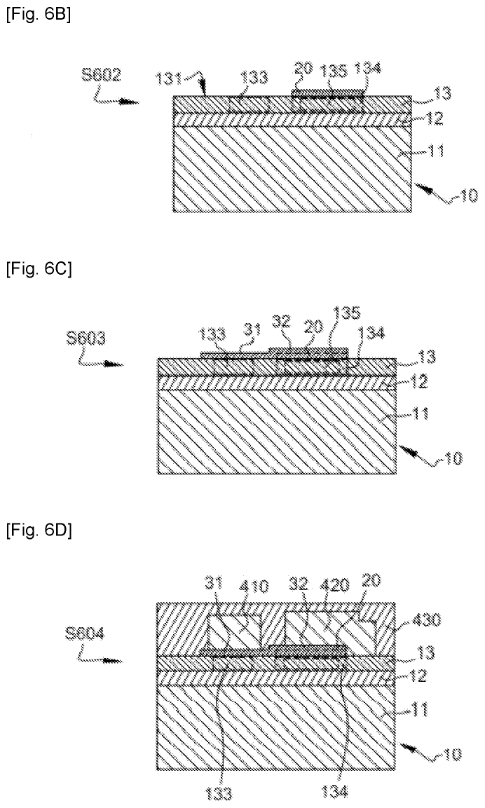

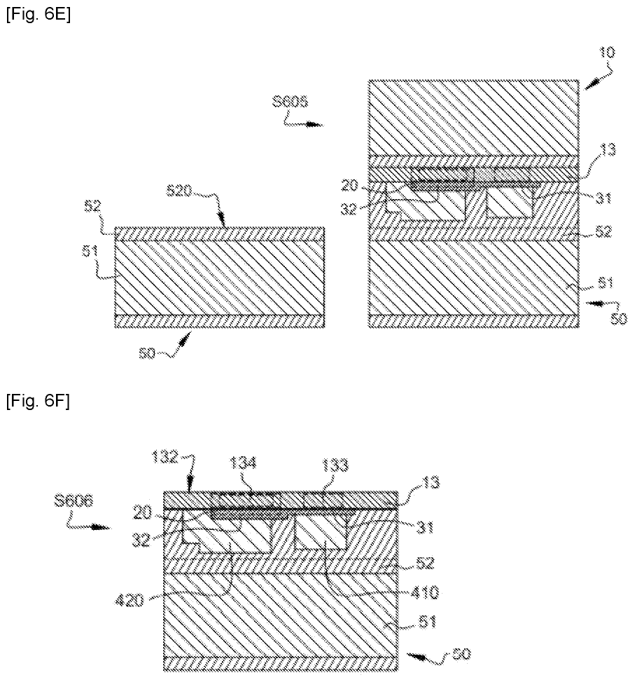

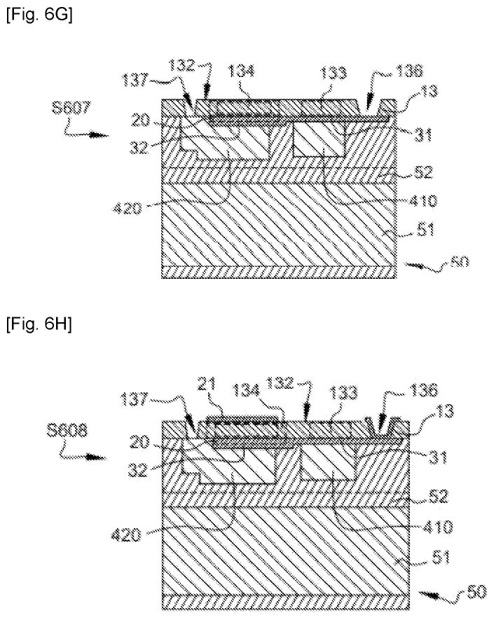

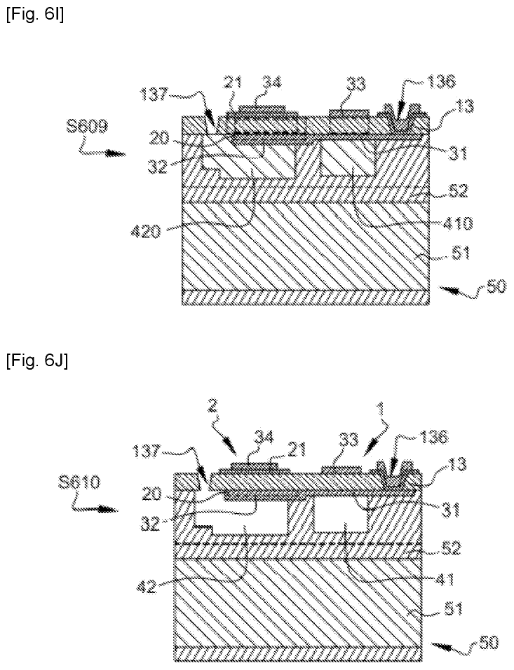

FIGS. 6A to 6J schematically represent the steps of a method 600 according to a third embodiment of the invention.

According to this third embodiment, the first and second resonators 1, 2 are of the FBAR type (see FIG. 6J), and the second resonator 2 receives a mass overload layer 20 at its lower electrode 32 and a mass overload layer 21 at its upper electrode 34. Beneficially, these mass overload layers 21, 22 are formed by the same metal material, for example aluminium, and are of identical thickness, equal to half the total thickness required to achieve the desired frequency offset for the resonant frequency of the second resonator 2.

The method 600 comprises the steps S601, S602, S603, S604, S605, S606, S607, S608, S609 and S610 represented in FIG. 6A, FIG. 6B, FIG. 6C, FIG. 6D, FIG. 6E, FIG. 6F, FIG. 6G, FIG. 6H, FIG. 6I and FIG. 6J respectively.

The first seven steps S601, S602, S603, S604, S605, S606, S607 are identical to the first seven steps S301, S302, S303, S304, S305, S306, S307 illustrated in FIGS. 3A, 3B, 3C, 3D, 3E, 3F, and 3G.

Steps S601 to S607 thus result in the same device (see FIG. 6G) as that represented in FIG. 3G.

Step S610 illustrated in FIG. 6J is also identical to step S309 illustrated in FIG. 3I.

The method 600 according to the third embodiment is distinguished from the method 300 according to the first embodiment in that it includes a step S608 of forming one or several mass overload patterns 21 on the second face 132 of the piezoelectric layer 13, at the second zone 134 (cf. FIG. 6H). This step S608 is analogous to step S507 represented in FIG. 5G of the method 500 according to the second embodiment.

Beneficially, the mass overload patterns 20 and 21 are formed by the same metal material and are of identical thickness. Thus, the mass overload is distributed and disposed symmetrically with respect to the piezoelectric layer.

This third embodiment is particularly beneficial when synthesising a very wide band filter (for example 600 MHZ). Indeed, for these bandwidth values, the frequency offset requires the use of mass layer thicknesses greater than 150 nm. Such a thickness, if achieved with a single mass overload pattern, can lead to asymmetry in the stack forming the second resonator 2. This asymmetry favours excitation of asymmetric vibration modes, such as the second-order resonance, which result in poorer rejection, that is lower attenuation, outside the bandwidth. By distributing the thickness of the overload layer symmetrically over two mass overload patterns, the third embodiment compensates for this drawback.

In common to the three embodiments just described, optional steps can be carried out at the end of the method, that is after step S309 of method 300, or after step S509 of method 500, or after step S610 of method 600.

These steps, which are not represented, consist, among other things, in
adding a passivation layer above the upper electrodes 33, 34, on the second face 132 (see FIG. 3I for example), this passivation layer defining the last layer (or upper layer) of the filter. The passivation layer protects the resonators 1, 2 from the ambient environment and thus improves their long-term reliability. The passivation layer is formed by a dielectric, for example silicon dioxide.
forming a metal layer, referred to as an over-metallisation layer, on the second face 132 (see FIG. 3I), only at the upper electrode 33 of the first resonator 1 and only at the upper electrode 34 of the second resonator 2. In the resonators 1 and 2 regions, this over-metallisation layer does not in any way cover the zones located outside the upper electrodes 33 and 34. The formation of the metal layer involves a combination of photolithography, etching and resin removal. Its purpose is to electrically consolidate the electrodes 33, 34 (the metal layer limits resistive losses of the upper electrodes 33, 34).

For FBAR type resonators, it may also be possible to form a passivation layer underneath the lower electrodes 31, 32, in addition to the passivation layer described above, in order to encapsulate the filter on both sides.

The various embodiments describe a filter comprising two bulk acoustic wave resonators. It will be appreciated that the method according to an aspect of the invention applies to a filter comprising several bulk acoustic wave resonators, for example between three and nine resonators.

The method (300, 500, 600) according to an embodiment of the invention makes it possible to make a broadband filter suitable for new generations of mobile communications by improving techniques of prior art, in particular by making it possible to use single-crystal piezoelectric materials and by making it possible to modify frequency of a bulk acoustic wave resonator (of the FBAR or SMR type) more significantly, while preserving electromechanical coupling coefficient and the electrodes of the resonators.

It will be appreciated that the various embodiments and aspects of the inventions described previously are combinable according to any technically permissible combinations.

The articles “a” and “an” may be employed in connection with various elements, components, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

1. A method for making a bandpass filter comprising a first bulk acoustic wave resonator and a second bulk acoustic wave resonator, the resonant frequency of the second resonator being offset from the resonant frequency of the first resonator by a predetermined offset, the method comprising:
providing a piezoelectric on insulator substrate, forming a donor substrate, comprising a piezoelectric layer at the top thereof,
forming a lower electrode of the first resonator on a first predefined zone of the piezoelectric layer, and a lower electrode of the second resonator on a second predefined zone of the piezoelectric layer,
assembling by bonding the donor substrate to a receiver substrate, so that the lower electrodes of the first and second resonators are disposed between the receiver substrate and the donor substrate,
removing, in assembling the receiver substrate and the donor substrate, the donor substrate with a barrier on the piezoelectric layer,
forming on the piezoelectric layer, an upper electrode of the first resonator at the first zone, and an upper electrode of the second resonator at the second zone,
forming the lower electrodes being preceded by a step of forming a mass overload pattern at the second zone, forming a mass overload pattern of the lower electrode,
and/or forming the upper electrodes being preceded by a step of forming a mass overload pattern in the second zone, forming a mass overload pattern of the upper electrode,
a total thickness of the mass overload pattern or patterns being chosen to offset resonant frequency of the second resonator by the predetermined offset,
each mass overload pattern being formed by lift-off of a sacrificial layer formed beforehand on the piezoelectric layer.

2. The method according to claim 1, wherein forming each mass overload pattern comprises the following sub-steps of:
depositing a sacrificial layer onto the entire surface of the piezoelectric layer,
defining an aperture through the sacrificial layer at the second zone, the aperture opening onto the piezoelectric layer at said second zone,
depositing a mass overload layer so as to cover the piezoelectric layer only at the aperture and to cover the sacrificial layer outside the aperture,
removing the stack formed by the sacrificial layer and the mass overload layer by lift-off removing the sacrificial layer, said removing leaving the mass overload layer on the piezoelectric layer only at the second zone to form the mass overload pattern.

3. The method according to claim 1, wherein the mass overload pattern of the lower electrode is formed by a material identical to the mass overload pattern of the upper electrode and has a thickness identical to said mass overload pattern of the upper electrode.

4. The method according to claim 1, wherein the mass overload pattern of the lower electrode is formed by a material identical to the material of the lower electrodes, and the mass overload pattern of the upper electrode is formed by a material identical to the material of the upper electrodes, and wherein the second zone is laterally wider than the second resonator.

5. The method according to claim 1, wherein the piezoelectric layer is formed by a single crystal piezoelectric material.

6. The method according to claim 5, wherein the single crystal piezoelectric material is selected from one of the following materials: lithium niobate, lithium tantalate, potassium niobate, and single crystal scandium.

7. The method according to claim 1, wherein the lower and upper electrodes are formed by one of the following materials: aluminium, molybdenum, tungsten, ruthenium, iridium.

8. The method according to claim 1, comprising forming a Bragg structure on the lower electrode of the first resonator and a Bragg structure on the lower electrode of the second resonator, said forming of the Bragg structures being carried out between forming the lower electrodes and the assembly step.

9. The method according to claim 1, comprising steps for forming an air cavity of the first resonator and an air cavity of the second resonator, said steps being as follows:
between forming the lower electrodes and the assembly step, forming a box on and around the lower electrode of the first resonator, and a box on and around the lower electrode of the second resonator, the boxes comprising a sacrificial layer,
after the assembly step and before forming the upper electrodes, forming through the piezoelectric layer an aperture to reach the box located on and around the lower electrode of the first resonator, and an aperture to reach the box located on and around the lower electrode of the second resonator,
after the step of forming the upper electrodes, removing the sacrificial layer through the apertures to release the boxes and fill them with air.

10. The method according to claim 1, comprising, after the step of forming the upper electrodes, an additional step of depositing onto the upper face of the band-pass filter and only onto the upper electrodes, a metal layer, forming an over-metallisation layer.
